(19) United States
(12) Patent Application Publication
(10) Pub. No.: US 2010/0279486 A1
(43) Pub. Date: Nov. 4, 2010

(54) NONVOLATILE MEMORY HAVING CONDUCTIVE FILM BETWEEN ADJACENT MEMORY CELLS

(76) Inventors: Carlo Cremonesi, Vaprio d'Adda (IT); Allesia Pavan, Merate (IT); Giorgio Servalli, Liserano (IT)

Correspondence Address: Gerbera/BSTZ;Blakely Sokoloff Taylor & Zafman LLP, 1279 OAKMEAD PARKWAY, SUNNYVALE, CA, 94085, US

(21) Appl. No.: 12/785,346

(22) Filed: May 21, 2010

Related U.S. Application Data
(62) Division of application No. 11/592,020, filed on Nov. 2, 2006, now abandoned.

(30) Foreign Application Priority Data
Nov. 11, 2005 (EP) EP 05110648.2

(51) Int. Cl. H01L 21/28; H01L 21/762; H01L 21/8247

(52) U.S. Cl. 438/424; 438/585; 438/595; 438/587; 257/E21.209; 257/E21.681; 257/E21.546

(57) ABSTRACT

A floating gate MOS transistor having a conductive floating gate electrode insulated from a semiconductor material having a main surface by a gate dielectric layer. At least one isolation region formed lateral to the gate electrode. An evacuation is formed in the isolation region and beneath the main surface of the semiconductor material layer. A conductive material fills the evacuation. A conductive control gate electrode is formed above the floating gate electrode. The floating gate electrode is laterally aligned to at least one isolation region.

### CROSS REFERENCE TO RELATED APPLICATIONS

This application claims the benefit of U.S. application Ser. No. 11/592,020 filed Nov. 2, 2006, entitled NONVOLATILE MEMORY HAVING CONDUCTIVE FILE MBETWEEN ADJACENT MEMORY CELLS, which claims priority to European Patent Application No. 05110648.2 filed Nov. 11, 2005, the entire contents of which are hereby incorporated by reference herein.

### FIELD OF THE INVENTION

The present invention relates generally to semiconductor devices and to methods for their manufacturing. In particular, the invention relates to floating gate non-volatile MOS memory devices and to methods for the manufacturing thereof.

### BACKGROUND ART

The past approaches described in the following could be pursued, but are not necessarily approaches that have been previously conceived or pursued. Therefore, unless otherwise indicated herein, the approaches described in the following are not to be considered prior art to the claims in this application merely due to the presence of these approaches in the following background description.

In the last years, the demand of increasing semiconductor device integration density has brought a reduction in the size of the elements used in integrated circuits.

For example, a semiconductor memory device which is commonly used in a number of applications to store information (either temporarily or permanently) should be able to store as many data as possible. Since semiconductor memory devices include large matrices of memory cells, a high memory cell density is required in order to increase the storage capacity of the semiconductor memory device and, at the same time, keep the die size from increasing. the smaller the size of the memory cells, the higher the memory cell density achievable.

On the other hand, the storage capacity of semiconductor memory devices can also be increased by providing memory cells each capable to storage more than just one bit of data, for example two or more data bits.

In particular, Flash semiconductor memory devices include matrices of floating gate MOS transistors. The floating gate MOS transistor used to form a Flash memory cell essentially is a MOSFET (acronym for Metal-Oxide-Semiconductor Field Effect Transistor) having a gate electrode consisting of a conductive control gate, a dielectric layer, a conductive floating gate and a tunnel oxide layer which are stacked over an active area (i.e., a channel region) of the MOS transistor.

Floating gate MOS transistors may store a logic value defined by their threshold voltage. The threshold voltage may be set to different levels, each one representing corresponding logical values stored in the memory cell. Particularly, in a two level flash memory the generic memory cell has a threshold voltage that can be set in either one of two different levels, thus enabling storage of one bit of data; in a multi-level (e.g., four-level) flash memory the threshold voltage of the generic cell may be set in more than two (for example, four) different levels, thus allowing storage of a plurality of (e.g., two) bits of data.

The threshold voltage depends on the electric charge on the floating gate, and it may be modified by injecting charge carriers, particularly electric charges like electrons into, or removing them from the floating gate. In more detail, a programming operation consists in the injection of electrons in the floating gate of the Flash memory cell, through a mechanism of tunneling across tunnel oxide (Fowler-Nordheim tunneling effect) or through a mechanism of injection of channel electrons “heated” by a suitable biasing voltage applied across the source and drain terminals (hot electron programming). An erasing operation consists in the removal of electrons from the floating gate of the Flash memory cell, through a mechanism of tunneling across tunnel oxide (Fowler-Nordheim tunneling effect) using a reverse voltage with respect to programming.

In a Flash semiconductor memory device, the memory cells may be arranged according to either a NAND or a NOR architecture.

In FIGS. 1A and 1B there are, by way of example, described a matrix portion 110 of a NAND flash memory, and a cross section along a word line of the matrix portion 110 according to the prior art.

In the memory matrix, the memory cells, labelled MC, are conventionally arranged by rows and columns, with the memory cells belonging to the same row sharing a control gate, formed by a conductive word line strip WL.

In the exemplary case considered of a NAND architecture, the memory cells of the same column are also grouped in a plurality of strings 111. Within each string 111, the memory cells MC (for example, 32 in number) are connected in series to each other between two select transistors ST1 and ST2, selectively enabling the connection of the string to a respective bit line BL, respectively to a source line SL. As visible in FIG. 1B, each memory cell is a floating gate MOS transistor having a gate electrode 121 completely self-aligned with an active region 122, formed in a (e.g., P type) substrate region 123, laterally delimited and separated from the active region of the adjacent memory cell(s) by STI (Shallow Trench Isolation) isolation regions 124. The generic isolation region 124 is formed by a corresponding trench 125, extending from a main surface 126 of the substrate region 123 to a trench depth, filled by one or more layers of silicon oxide.

The gate electrode 121 consists of a thin silicon oxide layer 127, forming the tunnel oxide, a polysilicon floating gate 128, an interpoly dielectric layer 129 and a polysilicon control gate 130, which are stacked on the active region 122 and self-aligned thereto.

The use of the STI isolation regions allows reducing the memory matrix area compared to other isolation techniques. A further reduction of the memory matrix area is made possible by the adoption of the NAND architecture, which substantially reduces the number of contacts.

With reference to FIG. 1A, during the reading operation, the select transistors ST1 and ST2 of the generic selected string 111 are turned on, the word line WL of the matrix row including the selected memory cell MC to be read is brought to a reading voltage while the other word lines are brought to a voltage sufficiently high to ensure that the corresponding memory cells MC are conductive irrespective of their threshold voltage. The selected memory cell MC is conductive if its threshold voltage is lower than the reading voltage, otherwise it is not conductive.

Due to the coupling capacitances Cd (shown in FIG. 1B) between the floating gates of adjacent cells, the actual potential which is applied to the floating gate of the selected cell through the coupling capacitance Cc with the control gate may be different from the expected one. As a consequence, the reading of the selected memory cell MC may be erroneous (for example, a memory cell that should be read as programmed may erroneously be considered erased). In other words, the capacitive coupling between the floating gates of adjacent cells makes the threshold voltage of the selected memory cell depend not only on the electric charge stored in its floating gate, but also on the electric charges stored in the floating gates of the adjacent cells. Such effect modifies the threshold voltage of the cells when the adjacent cells are programmed.

The above mentioned problem is also experienced during programming of the memory cells: for example, if a generic memory cell is verified as programmed at a certain stage of a program sequence, it may then be read as non-programmed when the program sequence is completed and the adjacent memory cells have been programmed as well.

The disturbing effect described above increases as the ratio between the coupling capacitance Cd with the floating gates of adjacent cells and the coupling capacitance Cc with the control gate increases.

The disturbances caused by the floating gate of the adjacent cells are in particular dangerous in multi-level memories, since the margins available for discriminating the different stored logic values are smaller.

The problem is exacerbated by the reduction of the width of the STI trenches, because this increases the coupling capacitances Cd between the floating gates of adjacent cells.

The above discussed problem has been addressed in the United States patent application US 2004/0012998, which discloses a NAND flash memory structure wherein, thanks to the fact that the word lines extend down between floating gates into isolation trenches until, within or past the level of gate oxide layer, thereby the word lines provide shielding from potentials in adjacent strings undergoing programming.

### SUMMARY OF THE INVENTION

The Applicant has addressed at least the problem of disturbances occurring during the reading operation of the memory device.

According to an aspect of the present invention, a solution is provided for manufacturing a self-aligned floating gate flash memory cell that, when inserted in a memory cell matrix, is less affected by disturbances induced by adjacent memory cells.

Particularly, an aspect of the present invention proposes a process for manufacturing a non-volatile memory cell including a floating gate MOS transistor, comprising the steps of: forming a gate dielectric over a surface of a semiconductor material layer; forming a conductive floating gate electrode insulated from the semiconductor material layer by the gate dielectric; forming at least one isolation region laterally to said floating gate electrode; excavating the at least one isolation region; filling the excavated isolation region with a conductive material, and forming a conductive control gate electrode of the floating gate MOS transistor insulatively over the floating gate. The step of forming the floating gate electrode includes laterally aligning said floating gate electrode to the at least one isolation region. The step of excavating includes: lowering an isolation region exposed surface below a floating gate exposed surface, said lowering exposing walls of the floating gate electrode; forming a protective layer on exposed walls of the floating gate electrode; and etching the at least one isolation region essentially down to the gate dielectric, the protective layer protecting against etching a portion of the isolation region near the gate dielectric.

### BRIEF DESCRIPTION OF THE DRAWINGS

The present invention, as well as further features and the advantages thereof will be best understood by reference to the following detailed description, given purely by way of a non-restrictive indication, to be read in conjunction with the accompanying drawings, wherein:

FIG. 1A schematically shows exemplary representations of a portion of a memory device according to the prior art;

FIG. 1B shows a cross-sectional view along a word line of a matrix portion according to the prior art;

FIGS. 2A through 2J are cross-sectional views illustrating the main steps of a manufacturing process of a floating gate MOS transistor according to a first embodiment of the present invention; and

FIGS. 3A through 3B are cross-sectional views illustrating the main steps of a manufacturing process of a floating gate MOS transistor according to a second embodiment of the present invention.

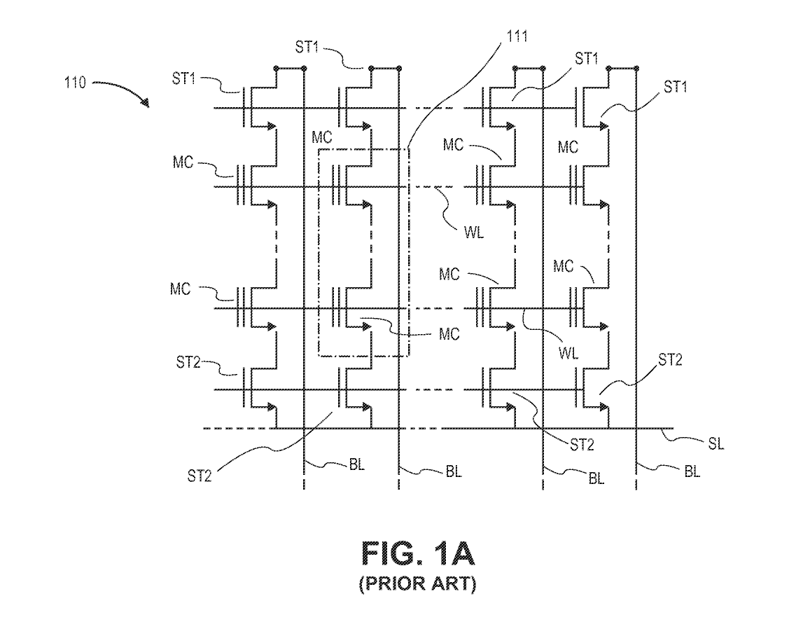

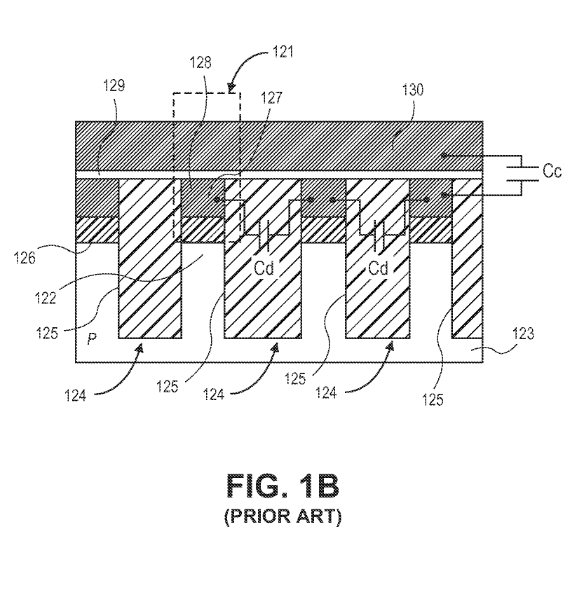

### DETAILED DESCRIPTION

In the following description, it should be noted that the drawings are not to scale: relative dimensions and proportions of parts of the drawings may have been increased or reduced in size for the sake of clarity.

It is pointed out that although in the drawings and in the following description the particular case of a NAND memory cell matrix is considered, this is not to be construed as a limitation of the invention, which can, for example, be straightforwardly applied to NOR memory cell matrices.

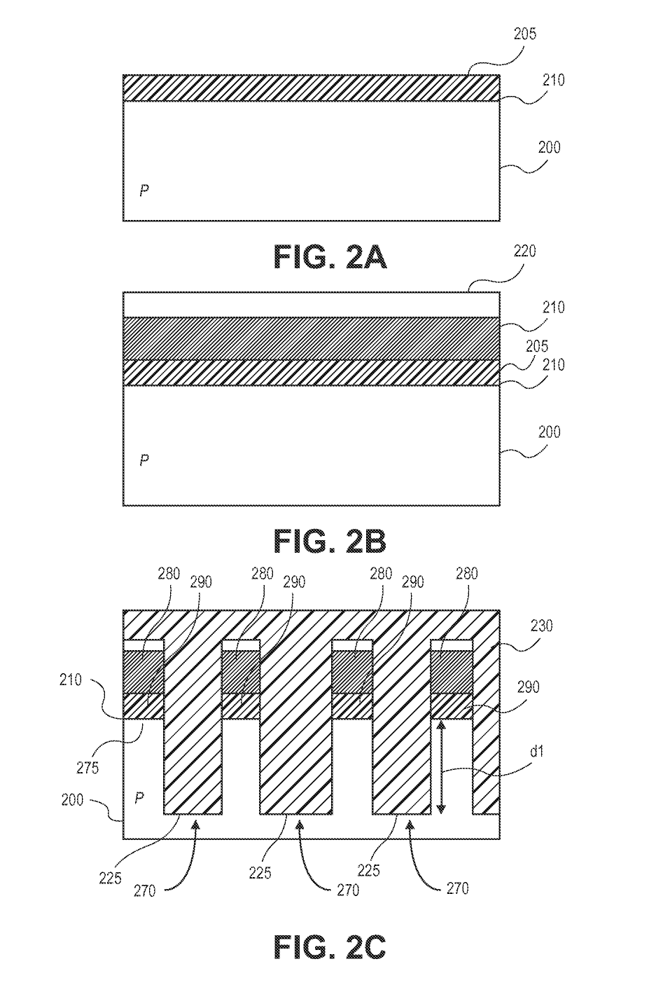

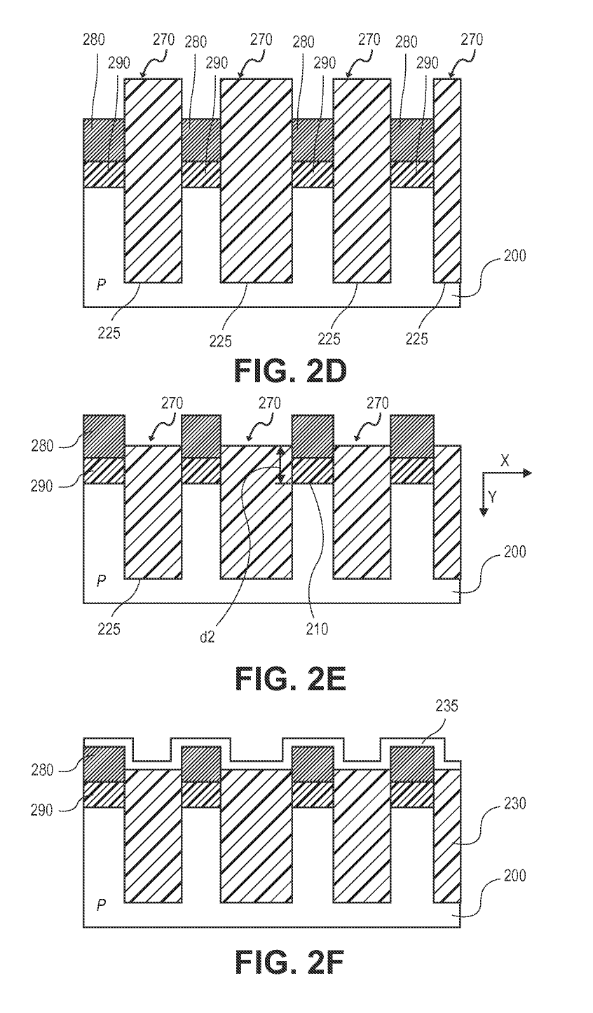

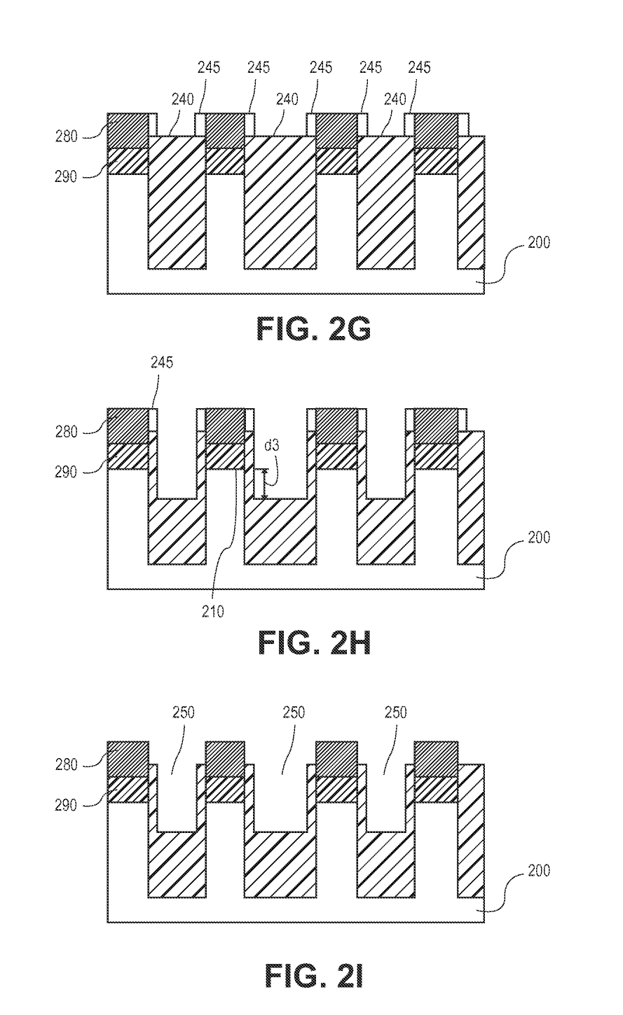

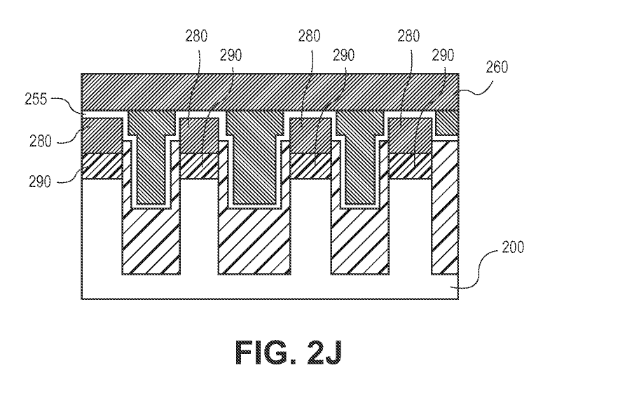

Referring to FIGS. 2A through 2J, a floating-gate MOS transistor memory cell manufacturing process according to a first embodiment of the present invention is described herein below; in particular the drawings are cross-sectional views of a portion of a memory cell matrix made along a matrix row, i.e. along a generic word line.

Considering in particular FIG. 2A, the starting material is a semiconductor substrate 200, for example, it may be a silicon wafer substrate of the P conductivity type, or a doped well, formed (possibly by means of a dedicated dopant implantation) inside a semiconductor layer, having for example a surface dopant concentration in the memory cell matrix ranging from approximately 5*10.sup.17 ions/cm.sup.3 to approximately 5*10.sup.19 ions/cm.sup.3.

Successively, a tunnel oxide layer 205, for example with a thickness ranging from 6 nm to 10 nm is formed on top of a main surface 210 of the substrate 200. Preferably, the tunnel oxide layer 205 includes a thermally grown silicon oxide layer; alternatively, it may be a silicon oxide layer which is deposited, for example, by means of a CVD (acronym for Chemical Vapor Deposition) process.

Moving to FIG. 2B, a polysilicon layer 215 and a nitride layer 220 are deposited on the tunnel oxide layer 205, for example by means of a CVD process. The polisilicon layer 215 (possibly doped) is adapted for forming the floating gates of the floating gate MOS transistors, while the silicon nitride layer 220 is used as hard mask for the subsequent definition of the isolation regions and/or as a stopping layer for the subsequent CMP (acronym for Chemical Mechanical Polishing) processes.

Moving the FIG. 2C, trenches 225, extending from the main surface 210 of the substrate region 200 down to an isolation depth d1 (for example, ranging from 100 nm to 300 nm), are excavated by selectively etching the layers 220, 215, 205 and 200. In particular, in order to form the trenches 225, a photoresist mask (not shown in the figure) is provided on the silicon nitride layer 220, so as to leave exposed areas of the layer 220 where the trenches 225 are to be formed. The nitride layer 220 is then selectively removed from such exposed areas, and the photoresist mask is stripped off; the remaining portions of nitride layer 220 form the hard mask for the subsequent etching. Using suitable etching techniques, the layers 215, 205 and 200 are selectively removed, down to the desired isolation depth d1, leaving polysilicon portions 280 and tunnel oxide portions 290. In particular, an anisotropic etching is performed, thereby the etch rate is much higher vertically than laterally.

Then, the trenches 225 are filled with an insulator, for example, albeit not limitatively field silicon dioxide 230. In such a way, isolation regions 270 are formed, adapted to isolate from each other active areas 275 in the substrate 200, which active areas 275 will form the channel regions of the memory cells. The etching steps leading to the formation of the isolation regions 270 also define (in the direction of the word lines) the polysilicon portions 280 (i.e., the floating gates of the memory cells); the floating gates 280 as a result being self-aligned to the isolation regions 270.

As shown in FIG. 2D, the field silicon dioxide layer 230 is then planarized down to the nitride silicon layer 220, for example by means of a CMP (acronym for Chemical Mechanical Polishing) process; the silicon nitride layer 220 is used as a stopping layer for stopping the planarization process. Then, the remaining portions of the silicon nitride layer 220 are etched away.

Moving to FIG. 2E, the field oxide layer 230 is selectively etched using, as an etching mask, the polysilicon floating gates 280. In particular, the etching process is selective against polysilicon and it can be both isotropic or anisotropic with respect to two directions X (lateral) and Y (vertical).

Specifically, the field oxide layer 230 corresponding to each isolation region 270 is etched to a depth such as to protrude a distance d2 from the main surface 210. The distance d2 is chosen so as to ensure that the tunnel oxide portions 290 are not affected during the etching of the field oxide layer 230. In particular, the distance d2 may range from approximately 30 nm to approximately 80 nm.

As shown in FIG. 2F, a relatively thin, conforming layer 235 of dielectric is deposited, for example by means of a CVD process, over the surface of the wafer; the conforming layer has a thickness such as to substantially follow the profile of the underlying layers. For example, the conforming layer 235 comprises a silicon nitride layer.

Moving to FIG. 2G, the conforming layer 235 is then selectively etched by means of an anisotropic etching process, so that the conforming layer 235 is essentially only removed from the horizontal exposed surfaces, thus leaving exposed field oxide portions 240 of the field oxide layer 230 and the surface of the floating gates 280. In such a way, silicon nitride spacers 245 are formed adjacent the vertical walls of the floating gates 280.

As shown in FIG. 2H, the exposed field oxide portions 240 are then etched by means of an etching process highly selective for silicon dioxide, that uses as a mask the silicon nitride spacers 245 and the floating gates 280. The etching process must be anisotropic such that the exposed field oxide portions 240 are etched preferably along the vertical direction, down to a depth d3 past the level of tunnel oxide portions 290 (i.e., a surface of the field oxide portions after the etching is recessed the depth d3 from the main surface 210). In particular, and by way of example, the depth d3 ranges from approximately 10 nm to approximately 30 nm.

Moving to FIG. 21, the silicon nitride spacers 245 are then removed by a suitable selective etching process, leaving between adjacent floating gates 280 recessed windows 250 adapted for accommodating subsequent material layers.

Then, as shown in FIG. 2J, a relatively thin, conforming interpoly dielectric layer 255 is deposited, for example by means of a CVD process, over the surface of the wafer, thus covering the walls of the recessed windows 250. The interpoly dielectric layer 255 may, for example, comprise a stack of layers SiO.sub.2/Si.sub.3N.sub.4/SiO.sub.2, referred to as ONO (acronym for Oxide/Nitride/Oxide) layer. The ONO layer 255 is relatively thin (for example, the thickness of the ONO layer 255 ranges from 10 nm to 18 nm). Afterwards, a polysilicon layer 260 is deposited over the whole surface, such as to substantially completely fill the recessed windows 250. The polysilicon layer 260 is then patterned to define word lines, each of which forms a common control gate for the memory cells of the word line. In particular, according to a conventional scheme, the polysilicon layer 260 and the ONO stack of layers 255 are etched, and at the same time the polysilicon floating gates 280 are defined in the direction orthogonal to the plane of the drawings. The complex of known operations follow that lead to the finished memory device.

Thanks to the fact that the polysilicon layer 260 fills the recessed windows 250, the coupling capacitances between the floating gates of adjacent memory cells are significantly reduced. In fact, the polysilicon layer 260 filling the recessed windows 250, being conductive, shields the floating gate of the generic selected cell from effects due to the charges stored on the floating gates of the adjacent cells.

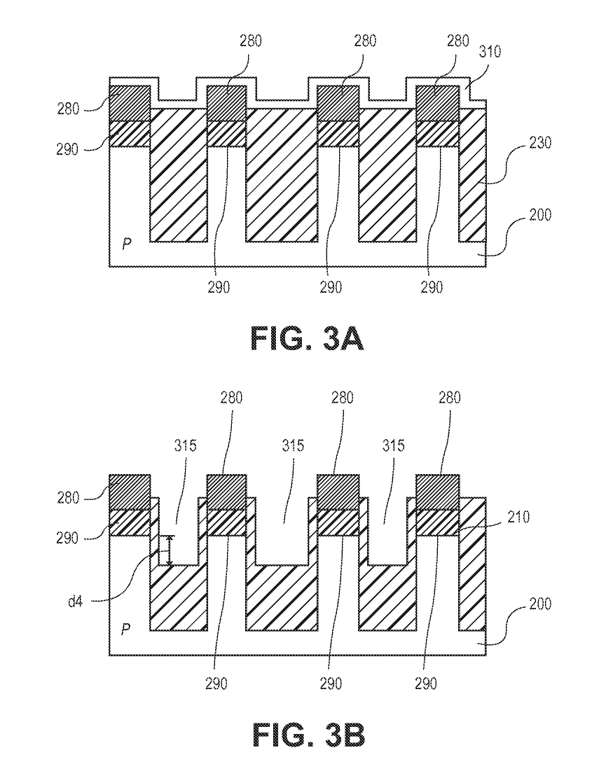

An alternative to the sequence of process phases just described, according to a second embodiment of the invention, comprises replacing the formation phase of the silicon nitride spacers 245 with the following process phases, shown in FIGS. 3A-3B.

In detail, the process proceeds similarly to the one described above up to the etching of the portions of field oxide layer 230 within the trenches 225 (FIG. 2E). Then, as shown in FIG. 3A, a relatively thin, conforming silicon oxide layer 310 is deposited, for example by means of CVD process, over the surface of the wafer. The thickness of the silicon oxide layer 310 is such that the layer 310 substantially follows the profile of the underlying layers (for example, the thickness may range from about 10 nm to about 30 nm).

Referring to FIG. 3B, the silicon oxide layer 310 and the portions of the field oxide layer 230 within the trenches 225 are etched by means of an anisotropic etching process down to a depth d4 past the level of the tunnel oxide portions 290, that is, the exposed surface of the field oxide filling the trenches is recessed from the main surface 210 a depth d4, which in particular may be equal to the depth d3 of the previous embodiment. The etching has an isotropic degree such that the layer 310 and the portions of field oxide filling the trenches 225 are etched preferably along the vertical direction. Thanks to the presence of the silicon oxide layer 310, as well as to the anisotropy of the etching process, it is avoided that the tunnel oxide portions 290 are etched during this phase.

As a result of the etching, recessed windows 315 are formed between the adjacent floating gates 280, which are adapted for accommodating the subsequent ONO layer 255 and polysilicon layer 260. From now on, the process proceeds following a known process scheme, particularly the patterning and definition of the word lines, that brings to the finished memory device.

Also in this embodiment, as mentioned in the foregoing, the recessed windows 315, being filled by conductive polysilicon layer, shielding the floating gates of adjacent memory cells and reduce the coupling capacitances there between. The floating gate potential of the generic selected memory cell is thus not affected by the charge present on the floating gates of the adjacent cells.

By the method just described, thanks to the present invention, it is possible to make a floating gate non-volatile memory device of very reduced size, wherein nevertheless the coupling capacitances with, and thus the effects of the adjacent memory cells of the memory matrix are very reduced.

Thanks to the present invention, the above results is achieved by means of relatively simple process steps and without adding masks so as to respect the reference process flow.

Moreover, it is particularly useful to apply the solution of the invention to multi-level flash memories, wherein the reduced threshold voltage margins between the different programming states make the correct operation of the memory cells particularly critical in the presence of coupling capacitances between adjacent cells.

Moreover, the method according to the invention is very advantageous in the case of NOR and NAND flash type or multilevel floating-gate non volatile semiconductor memory devices, but it can be applied to any semiconductor device in which is necessary to have a reduced coupling capacitance between adjacent memory cells.

Naturally, in order to satisfy local and specific requirements, a person skilled in the art may apply, to the solution described above, many modifications and alterations. Particularly, although the present invention has been described with a certain degree of particularity with reference to preferred embodiments thereof, it should be understood that various omissions, substitutions and changes in the form and details as well as other embodiments are possible; moreover, it is expressly intended that specific elements and/or method steps described in connection with any disclosed embodiment of the invention may be incorporated in any other embodiment as a general matter of design choice.

For example, although in the preceding description reference has been made to a P-type substrate, the conductivity type of the region may be reversed.

In addition, it is not strictly necessary that the recessed windows 250 or 315 extend past the level of the tunnel oxide layer: a significant reduction of the coupling capacitances may also be obtained with more shallow recessed windows.

Moreover, the recessed windows may have different shapes.

The shape and depth of the trenches may greatly vary.

In addition, it is possible to use other profiles of the dopant concentrations.

In any case, the use of alternative processes for realizing the proposed floating gate MOS transistor is possible.

For example, it is possible to grow a sacrificial oxide layer over the substrate before fowling the tunnel oxide layer.

Moreover, before filling the trenches with the insulating layer, a thin layer of silicon oxide may be formed to cover the walls of the trenches.

In addition, although in the preceding description of the first invention embodiment a conforming nitride layer is deposited in order to form the spacers, a stack of relatively thin, conforming silicon dioxide layer and nitride layer may be formed.

Having thus described at least one illustrative embodiment of the invention, various alterations, modifications, and improvements will readily occur to those skilled in the art. Such alterations, modifications, and improvements are intended to be within the scope of the invention. Accordingly, the foregoing description is by way of example only and is not intended as limiting. The invention is limited only as defined in the following claims and the equivalents thereto.

What is claimed is:

1. A process for manufacturing a non-volatile memory cell including a floating gate MOS transistor, comprising:
forming a gate dielectric over a surface of a semiconductor material layer;
forming a conductive floating gate electrode insulated from the semiconductor material layer by the gate dielectric;
forming at least one isolation region laterally to said floating gate electrode;
excavating the at least one isolation region;
filling the excavated isolation region with a conductive material; and
forming a conductive control gate electrode of the floating gate MOS transistor insulatively over the floating gate,
wherein forming the floating gate electrode includes laterally aligning said floating gate electrode to the at least one isolation region; and
wherein the step of excavating includes lowering an isolation region exposed surface below a floating gate electrode exposed surface, said lowering exposing walls of the floating gate electrode forming a protective layer on exposed walls of the floating gate electrode, and etching the at least one isolation region essentially down to the gate dielectric, the protective layer protecting against etching a portion of the at least one isolation region near the gate dielectric.

2. The method according to claim 1, wherein forming the gate dielectric, forming the conductive floating gate electrode and forming the at least one isolation region includes:
forming a gate dielectric layer over a surface of the semiconductor material layer;
forming a conductive floating gate layer;
forming at least one trench extending into the semiconductor material layer,
wherein said forming the at least one trench includes defining said floating gate electrode in a self-aligned way to the trench;
forming an insulating layer, said insulating layer filling the at least one trench.

3. The method according to claim 2, wherein the step of filling the at least one trench includes:
planarizing the insulating layer through a chemical mechanical polishing process.

4. The method according to claim 2, wherein said forming the at least one trench includes:
forming a stopping layer over the conductive floating gate layer.

5. The method according to claim 4, wherein the stopping layer includes a silicon nitride layer.

6. The method according to claim 1, wherein lowering includes etching the planarized insulating layer.

7. The method according to claim 1, wherein forming the protective layer includes:
forming a conforming insulating layer over the isolation region exposed surface and on the exposed walls of the floating gate electrode; and
anisotropically etching the conforming insulating layer so as to form sidewall spacers adjacent the walls of the floating gate electrode.

8. The method according to claim 7, wherein the conforming insulating layer includes a first silicon nitride layer.

9. The method according to claim 7, wherein the conforming insulating layer includes a sequence of an oxide layer and a silicon nitride layer.

10. The method according to claim 1, wherein forming the protective layer includes:
forming a conforming insulating layer over the isolation region exposed surface and on the exposed walls of the floating gate electrode; and
selectively etching the conforming insulating layer.

11. The method according to claim 10, wherein the conforming insulating layer includes a silicon oxide layer.

12. The method according to claim 1, wherein filling the excavated is isolation region with a conductive material and forming a conductive control gate electrode of the floating gate MOS transistor includes:
depositing a polycrystalline silicon layer, and
patterning the polycrystalline silicon layer to form the conductive control gate electrode.

13. A method of manufacturing a semiconductor memory device, comprising:
forming an arrangement of memory cells, each memory cell including a floating gate MOS transistor, and
isolating the memory cells from each other by means of isolation regions,
wherein said memory cells are formed according to claim 1.
